(19) United States
(12) Patent Application Publication
(10) Pub. No.: US 2026/0358423 A1
(43) Pub. Date: Nov. 12, 2026

(54) RECHARGEABLE BATTERY CAPACITY UPDATE

(71) Applicant: Medtronic, Inc., Minneapolis, MN (US)

(72) Inventor: Gang Ji, Medina, MN (US)

(21) Appl. No.: 19/136,049

(22) PCT Filed: Nov. 17, 2023
(86) PCT No.: PCT/IB2023/061647

§ 371 Date: Jun. 5, 2025

Related U.S. Application Data
(60) Provisional application No. 63/386,604, filed on Dec. 8, 2022.

(51) Int. Cl. G01R 31/367; G01R 31/374; G01R 31/3842

(52) U.S. Cl. CPC G01R 31/367; G01R 31/374; G01R 31/3842

(57) ABSTRACT

Example devices and techniques are described herein for determining a relative state-of-charge of a battery. The device may determine a present moving average voltage based on at least one of a plurality of battery voltages and determine at least one of that the battery is coming out of reset or that the moving average of the battery voltage is stable. The device may determine present capacity fade parameters. The device may determine respective freshness factors and determine a weighted moving average incremental capacity fade coefficient based at least in part on the present capacity fade parameters. The device may determine a present battery capacity based on the weighted moving average incremental capacity fade coefficient and a previous determined battery capacity.

This application claims the benefit of U.S. Provisional Patent Application Ser. No. 63/386,604, filed 8 Dec. 2022, the entire content of which is incorporated herein by reference.

### TECHNICAL FIELD

The disclosure relates to rechargeable batteries and, more particularly, to devices and techniques for updating a battery capacity of a rechargeable battery.

### BACKGROUND

Many devices, including implantable medical devices, wearable devices, laptop computers, tablet computers, and cellular phones, among others, utilize rechargeable batteries. These devices also typically include a battery management system, which may include a battery management system (BMS) including a fuel gauge, that may provide a user of the device with a representation of a relative state-of-charge (SOC) of the battery, such as how fully charged the battery may be.

### SUMMARY

In some aspects, the disclosure is directed to devices that utilize rechargeable batteries, such as implantable medical devices (IMDs), wearable devices (e.g., insulin pumps, smart watches, patches, etc.), autoclavable surgical tools, laptop computers, tablet computers, cellular phones, or the like, and techniques for such devices to update a battery capacity of a rechargeable battery, such that an estimated relative SOC may be more accurate than if the battery capacity were not updated.

As a rechargeable battery ages, the capacity of the rechargeable battery fades due, for example, to the loss or expending of the active materials of the rechargeable battery. To provide an accurate estimation of a relative SOC of the rechargeable battery as the capacity of the rechargeable battery fades, it may be desirable to track and measure the capacity of a rechargeable battery in the field. For example, a relative SOC of a rechargeable battery may be a represented as percentage of the battery capacity. If an outdated value is used for the capacity of the rechargeable battery when determining the relative SOC of the rechargeable battery, the relative SOC may be erroneous, over-representing the actual relative SOC. This may lead to the device powered by the rechargeable battery shutting down sooner expected by a user of the device who has viewed a representation of the erroneous, over-represented relative SOC. This may be an undesirable outcome for the user.

The techniques of this disclosure include sampling battery voltages over time of the rechargeable battery and using sampled battery voltages to determine a present moving average voltage. If the battery is coming out of reset (e.g., was just powered on) or if the present moving average voltage is stable, these techniques may include determining present capacity fade parameters. Such capacity fade parameters may include a present incremental capacity fade coefficient, a present delta SOC, and a timestamp associated with the present incremental capacity fade coefficient and the present delta SOC. For example, the timestamp may be indicative of a time at which the present incremental capacity fade coefficient and the present delta SOC was determined and/or the time at which the most recent battery voltage was sampled that was used to determine the present incremental capacity fade coefficient and the present delta SOC. These techniques may include determining a weighted moving average incremental capacity fade coefficient based on a plurality of incremental capacity fade coefficients, respective delta SOCs, and/or respective freshness factors. The techniques may also include determining a present battery capacity based on the weighted moving average incremental capacity fade coefficient and a previous determined battery capacity. This present battery capacity may be used, for example, to calculate a present relative SOC, which may be output so that a user may be better able to determine whether to charge the battery.

In one example, the disclosure is directed to a device including a memory configured to store a plurality of capacity fade parameters; a battery; a temperature sensor, the temperature sensor being configured to sense a battery temperature of the battery; and processing circuitry coupled to the memory and the temperature sensor, the processing circuitry being configured to: determine a plurality of battery voltages of the battery over time; determine a present moving average voltage based on at least one of the plurality of battery voltages; determine at least one of that the battery is coming out of reset or that the moving average of the battery voltage is stable; based on the at least one of the battery coming out of reset or the moving average of the battery voltage being stable, determine present capacity fade parameters, the present capacity fade parameters comprising a present incremental capacity fade coefficient, a present delta state-of-charge (SOC), and a timestamp associated with the present incremental capacity fade coefficient and the present delta SOC; determine respective freshness factors; determine a weighted moving average incremental capacity fade coefficient based on plurality of incremental capacity fade coefficients, respective delta SOCs, and respective freshness factors; and determine a present battery capacity based on the weighted moving average incremental capacity fade coefficient and a previous determined battery capacity.

In another example, the disclosure is directed to a method including determining a plurality of battery voltages of a battery over time; determining a present moving average voltage based on at least one of the plurality of battery voltages; determining at least one of that the battery is coming out of reset or that the moving average of the battery voltage is stable; based on the at least one of the battery coming out of reset or the moving average of the battery voltage being stable, determining present capacity fade parameters, the present capacity fade parameters comprising a present incremental capacity fade coefficient, a present delta state-of-charge (SOC), and a timestamp associated with the present incremental capacity fade coefficient and the present delta SOC; determining respective freshness factors; determining a weighted moving average incremental capacity fade coefficient based on plurality of incremental capacity fade coefficients, respective delta SOCs, and respective freshness factors; and determining a present battery capacity based on the weighted moving average incremental capacity fade coefficient and a previous determined battery capacity.

In another example, the disclosure is directed to a non-transitory storage medium comprising instructions that when executed by one or more processors cause the one or more processors to: determine a plurality of battery voltages of a battery over time; determine a present moving average voltage based on at least one of the plurality of battery voltages; determine at least one of that the battery is coming out of reset or that the moving average of the battery voltage is stable; based on the at least one of the battery coming out of reset or the moving average of the battery voltage being stable, determine present capacity fade parameters, the present capacity fade parameters comprising a present incremental capacity fade coefficient, a present delta state-of-charge (SOC), and a timestamp associated with the present incremental capacity fade coefficient and the present delta SOC; determine respective freshness factors; determine a weighted moving average incremental capacity fade coefficient based on plurality of incremental capacity fade coefficients, respective delta SOCs, and respective freshness factors; and determine a present battery capacity based on the weighted moving average incremental capacity fade coefficient and a previous determined battery capacity.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram of an example device having a rechargeable battery in accordance with one or more techniques of this disclosure.

FIG. 2 is a graph illustrating a change in battery capacity over time.

FIG. 3 is a flow diagram illustrating example rechargeable battery capacity update techniques according to one or more aspects of this disclosure.

FIG. 4 is a flow diagram illustrating example techniques for determining whether the battery voltage is stable enough for an open circuit voltage (OCV) determination according to one or more aspects of this disclosure.

FIG. 5 is a flow diagram illustrating example techniques for determining the present capacity fade parameters according to one or more aspects of this disclosure.

FIG. 6 is a flow diagram illustrating example techniques for determining the weighted moving average of the incremental capacity fade coefficients according to one or more aspects of this disclosure.

FIG. 7 is a flow diagram illustrating example techniques for determining a present battery capacity according to one or more aspects of this disclosure.

### DETAILED DESCRIPTION

A variety of devices may utilize rechargeable batteries as a power source for operational power. For example, an IMD, a wearable device (e.g., an insulin pump, smart watch, patch, etc.), an autoclavable surgical tool, a laptop computer, a tablet computer, a cellular phone or any other device may utilize a rechargeable battery to power its operations. An implantable medical device (IMD) that provides cardiac rhythm management therapy to a patient, monitors one or more physiological parameters of the patient, and/or provides neurostimulation therapy to the patient may include a rechargeable battery to supply power for the generation of electrical therapy or other functions of the IMD. As another example, a left-ventricular assist device (LVAD) may include a rechargeable battery to supply power for a pump and other functions of the LVAD. Rechargeable batteries typically include processing circuitry (e.g., of a BMS/fuel gauge) that monitors the rechargeable battery and provides information regarding the state of the rechargeable battery to a device, such as an IMD, a laptop computer, a tablet, a cellular phone, or other device. Such information may include a relative SOC, for example, which may indicate an estimate of a percentage to which the rechargeable battery is charged. For example, if the rechargeable battery is fully charged, the device may represent the relative SOC as 100%. After some use without charging, the rechargeable battery will have been partially discharged. In such a case, the device may represent the relative SOC as some percentage of which the rechargeable is charges which is less than 100%, for example, 80%.

The accurate fuel gauging of a rechargeable battery may be critical for the safe and effective operation of many applications, including medical applications. For example, one may want to recharge a rechargeable battery of a medical device if the SOC of the rechargeable battery is too low to power therapy circuitry previous to attempting to provide such therapy.

A commercial off-the-shelf BMS typically requires a significant amount of energy to be charged or discharged from the rechargeable battery in order to determine the battery capacity. However, in some use-cases, this requirement may be very challenging to achieve under normal operating conditions of a device. For example, a device running a large so-call “maintenance cycle” on a rechargeable battery may significantly reduce the available energy from the rechargeable battery, which may not be acceptable for many mission-critical devices, such as medical devices.

The techniques described herein may significantly reduce the required amount of energy to be charged or discharged for the battery capacity determination of a rechargeable battery. Therefore, the processing circuitry may determine the battery capacity over multiple small charge and/or discharge cycles, rather than one large cycle. This may greatly increase the likelihood of a successful capacity determination in the field and/or reduce the potential negative impact of the maintenance cycle. For example, to minimize the impact of uncertainty from using smaller cycle(s) to determine the battery capacity, processing circuitry may determine and utilize a two-fold weighted moving average incremental capacity fade coefficient. For example, a device may determine a plurality of incremental capacity fade coefficients and weight every incremental capacity fade coefficient by a size of an associated delta SOC and an age (e.g., staleness or freshness) of the particular incremental capacity fade coefficient compared to the present incremental capacity fade coefficient.

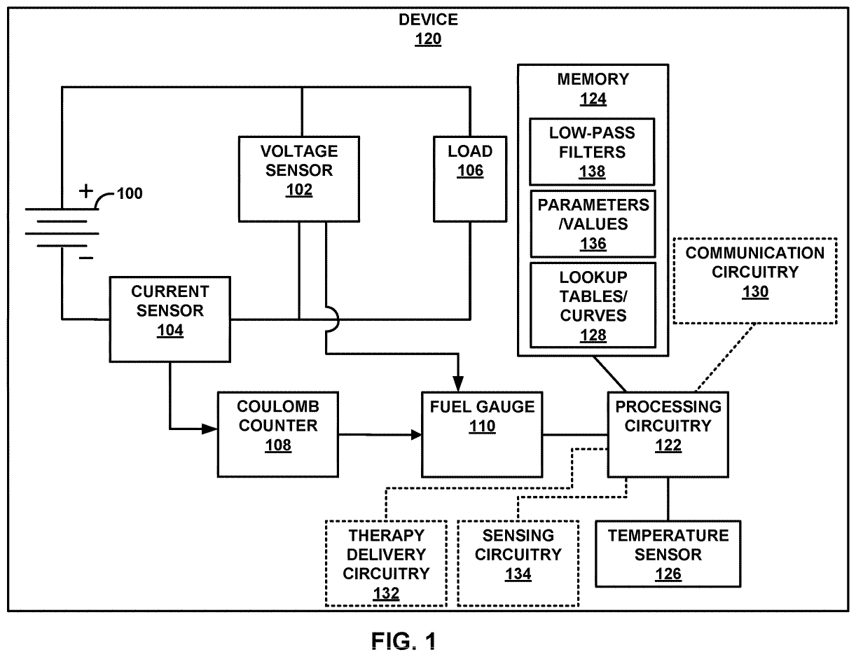

FIG. 1 is a block diagram of an example device having a rechargeable battery in accordance with one or more techniques of this disclosure. FIG. 1 depicts a device 120, which may be an IMD, a wearable device (e.g., an insulin pump, smart watch, patch, etc.), an autoclavable surgical tool, a laptop computer, a tablet, a cellular phone or any other device that utilizes a rechargeable battery to power its operations. Device 120 includes battery 100, voltage sensor 102, current sensor 104, load 106, coulomb counter 108, fuel gauge 110, processing circuitry 122, temperature sensor 126, and memory 124. In some examples, device 120 may include only one of voltage sensor 102 or coulomb counter 108. In some examples, such as where device 120 represents an IMD or a cellular phone, device 120 may include communication circuitry 130. Communication circuitry 130 is represented in dashed lines as communication circuitry 130 may not be present in all examples of device 120.

In some examples, device 120 may include other circuitry or functionality. For example, device 120 may include therapy delivery circuitry 132, in examples where device 120 is configured to deliver therapy to a user of device 120. For example, therapy delivery circuitry 132 may include circuitry for generating an electrical stimulation signal, a shock, or the like, and delivering the therapy via electrodes (not shown). In some examples, therapy delivery circuitry 132 may include circuitry for controlling a reservoir which may hold a medication, such as insulin, and therapy delivery circuitry 132 may be configured to control the reservoir (not shown) to release a bolus of medication based on one or more sensed physiological parameters, such as a blood sugar level. In some examples, therapy delivery circuitry 132 may perform functions of autoclavable surgical instruments.

In some examples, device 120 may include sensing circuitry/sensors 134. Sensing circuitry/sensors 134 may be configured to sense one or more physiological parameters of a patient, sense a location of the user of device 120, sense an orientation of device 120, or the like. In some examples, processing circuitry 122 may control therapy delivery circuitry 132 or other elements of device 120 based on output of sensing circuitry/sensors 134. In some examples, sensing circuitry/sensors 134 may include one or more imaging sensors configured to sense anatomy of a patient.

Battery 100 may be a rechargeable battery that provides power to device 120. Voltage sensor 102 may measure the voltage across load 106 and output the measured voltage to fuel gauge 110. Current sensor 104 may measure a current flowing through device 120 and output the measured current to coulomb counter 108. Coulomb counter 108 may be configured to track the measured current over time and determine a total sum of energy entering or leaving battery 100. Coulomb counter 108 may output the total sum of energy entering or leaving battery 100 to fuel gauge 110.

Processing circuitry 122 may include one or more general purpose microprocessors, digital signal processors (DSPs), application specific integrated circuits (ASICs), field programmable logic arrays (FPGAs), or other equivalent integrated or discrete logic circuitry. Processing circuitry 122 may be configured to execute computer-readable instructions, which may be stored in memory 124, to provide various functionality to device 120. While shown separate from fuel gauge 110, in some examples, fuel gauge 110 may be part of processing circuitry 122.

Memory 124 may store such instructions as mentioned above. Memory 124 may also store lookup tables/curves 128. Lookup tables/curves 128 may include the lookup tables and/or curves described herein which may be used by fuel gauge 110 (and/or processing circuitry 122) to determine a weighted incremental capacity fade as discussed herein which may be used to update a battery capacity so as to enable device 120 to provide a more accurate SOC (and/or relative SOC) than if the battery capacity were not updated. Memory 124 may also store parameters 136. Parameters/values 136 may include capacity fade parameters, such as incremental capacity fade coefficients, delta state-of-charge (SOC)s, and timestamps associated therewith. Parameters/values 136 may also include other values discussed herein as being stored in memory. Memory 124 may also include low-pass filters 138. Low-pass filters 138 may include a first low-pass filter that may be used by processing circuitry 122 (or fuel gauge 110) to determine a present moving average voltage based on a plurality of battery voltages and a second low-pass filter that may be used by processing circuitry 122 to filter a difference between a present moving average voltage and a previous moving average voltage. In some examples, one or both of the first and second low-pass filters may be finite impulse response (FIR) filters. In some examples, one or both of the first and second low-pass filters may be programmable. The first and the second low-pass filters may be the same or may be different. In some examples, rather than being stored in memory 124, the first and/or the second low-pass filter may be implemented in circuitry in device 120.

Temperature sensor 126 may be configured to sense or measure an operating temperature of battery 100, of a battery pack (not shown), of device 120, or the like. Batteries, like battery 100, may be sensitive to temperature, so more accurate determination of a weighted moving average incremental capacity fade coefficient of battery 100 may take temperature into account. As such, lookup tables may include different entries, different tables, and/or different curves for different battery temperatures.

While load 106 is shown separately, load 106 may include other components of device 120, such as processing circuitry 122, etc. It should be noted that device 120 may include other components which are not shown such as stimulation generation circuitry, battery recharge circuitry, a user interface which may display a relative SOC, or the like.

Device 120 may include electronics and other internal components necessary or desirable for executing the functions associated with the device. In one example, device 120 includes one or more of processing circuitry 122, memory 124, therapy delivery circuitry 132, sensing circuitry 134, communication circuitry 130, temperature sensor 126, and a power source (e.g., battery 100). In general, memory 124 of device 120 may include computer-readable instructions that, when executed by processing circuitry 122 of device 120, cause it to perform various functions attributed to the device herein.

Device 120 may include or may be one or more processors or processing circuitry, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor” and “processing circuitry” as used herein may refer to any of the foregoing structure or any other structure suitable for implementation of the techniques described herein.

Memory 124 may include any volatile or non-volatile media, such as a random-access memory (RAM), read only memory (ROM), non-volatile RAM (NVRAM), electrically erasable programmable ROM (EEPROM), flash memory, and the like. Memory 124 may be a storage device or other non-transitory medium.

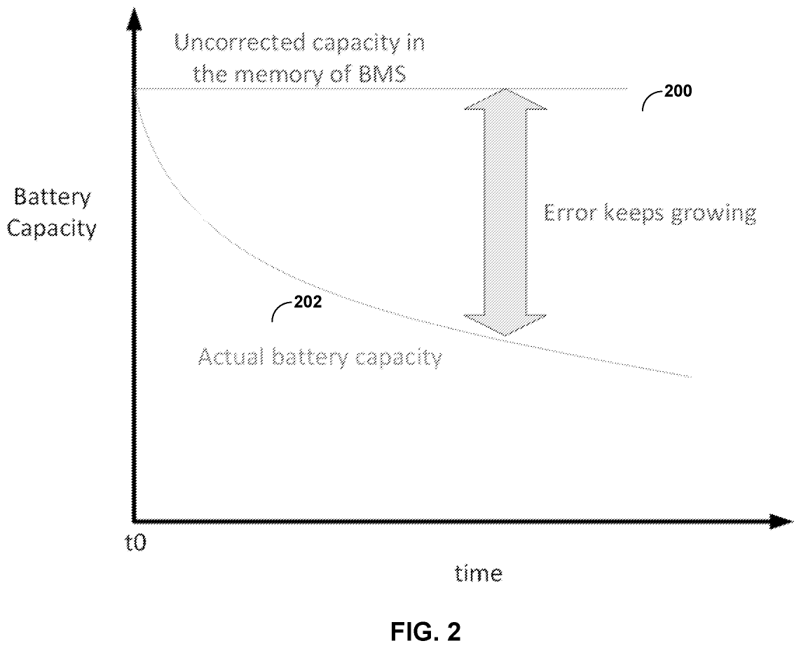

FIG. 2 is a graph illustrating a change in battery capacity over time. Battery capacity value 200 represents the battery capacity value stored in memory 14. Battery capacity value 200 may be provided to a manufacturer of device 120 by a manufacturer battery 100 and be stored in memory 14 by the manufacturer of device 120. However, actual battery capacity 202 changes as rechargeable battery 100 ages in the field over time. As can be seen, the difference between battery capacity value 200 and actual battery capacity 202 keeps growing over time. So, the older rechargeable battery 100 becomes, the more erroneous a determined relative SOC may become as device 120 may determine the relative SOC based on battery capacity value 200 rather than actual battery capacity 202.

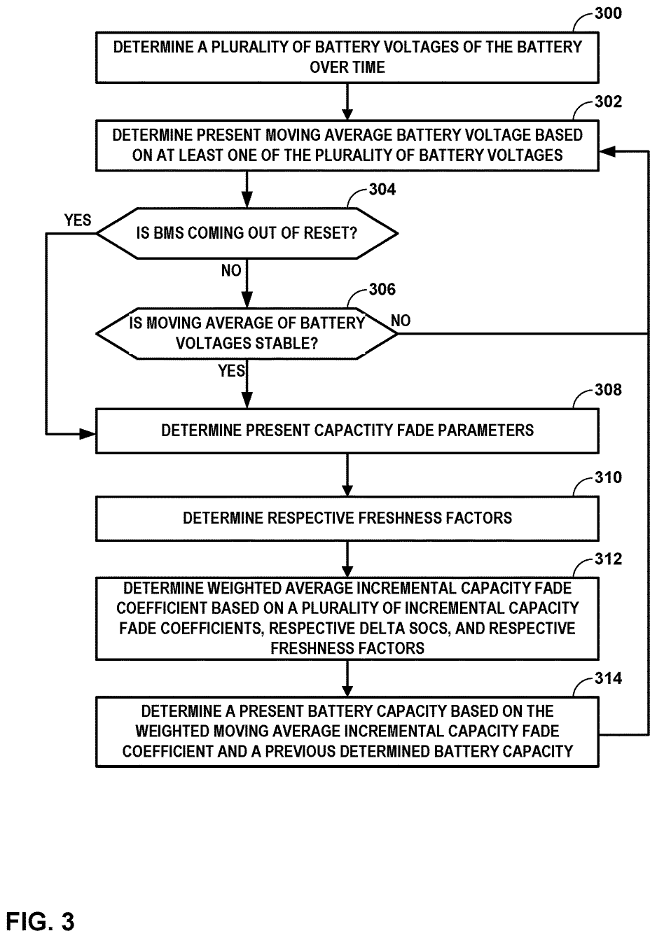

FIG. 3 is a flow diagram illustrating example rechargeable battery capacity update techniques according to one or more aspects of this disclosure. While discussed with respect to processing circuitry 122, the example of FIG. 3 may be performed by fuel gauge 110, processing circuitry 122, processing circuitry of another device(s) (e.g., one or more devices external to device 120), or any combination thereof.

Processing circuitry 122 may determine a plurality of battery voltages of the battery over time (300). For example, processing circuitry 122 may obtain samples of a plurality of voltages (e.g., voltage values) of battery 100 over time via voltage sensor 102. For example, processing circuitry 122 may obtain the plurality of voltages continuously, periodically, or from time-to-time.

Processing circuitry 122 may determine a present moving average voltage based on at least one of the plurality of battery voltages (302). For example, processing circuitry 122 may apply a low-pass filter of low-pass filters 138, such as a finite impulse response (FIR) filter, to one or more of the plurality of voltages to determine the present moving average voltage. In some examples, the low-pass filter may be configured to utilize a limited time window such that all of plurality of battery voltages may not be used when determining the present moving average voltage. For example, the low-pass filter may only use a portion or subset of the plurality of battery voltages, the portion or subset being less than an entirety or all of the plurality of battery voltages.

Processing circuitry 122 may determine at least one of a) that the battery is coming out of reset, or b) that the present moving average voltage is stable. Such a determination may be indicative of whether a sensed battery voltage is equal to or approximately equal to an open circuitry voltage (OCV) of battery 100. An OCV may be used to determine an SOC via an OCV to SOC lookup table of lookup tables/curves 128. For example, processing circuitry 122 may determine an SOC based on a voltage of battery 100 through the use of an OCV to SOC lookup table. Using a battery voltage that is not equal to or approximately equal to the OCV of battery 100 when using such a lookup table may result in an erroneous SOC value, and it may be desirable to avoid using such a battery voltage.

For example, if either battery 100 is coming out of reset or the present moving average voltage is stable, processing circuitry 122 may proceed to box 308. If neither battery 100 is coming out of reset nor the present moving average voltage is stable, processing circuitry 122 may return to box 302 (or alternatively, to box 300).

In one example, to determine the at least one of that the battery is coming out of reset or that the present moving average voltage is stable, processing circuitry 122 may proceed as shown in FIG. 3. It should be noted that other examples, may exist, such as reversing the determinations shown in boxes 304 and 306, or the like, and such examples are contemplated by this disclosure.

In some examples, processing circuitry 122 may determine if battery 100 is coming out of reset (304). For example, processing circuitry 122 may determine if device 120 was just powered on (e.g., device 120 was powered on within a predetermined period of time) or if battery 100 was just woken up from a shut-down mode (e.g., was woken up within a predetermined period of time). In some examples, such a predetermined period of time may be in the range of tens of seconds to several minutes. For example, if battery 100 is just coming out of a reset, then a present voltage sensed by voltage sensor 102 may be equal or approximately equal to an OCV of battery 100.

If battery 100 is not coming out of reset (the “NO” path from box 304), processing circuitry 122 may determine if the present moving average voltage is stable (306). For example, after battery 100 exits from either a charge or discharge event, the voltage of battery 100 may slowly reach an OCV level. If processing circuitry 122 determines an OCV of battery 100 as being equal to a present voltage of battery 100 before the battery voltage is stable (e.g., when the OCV of battery 100 is not equal to or approximately equal to the present voltage of battery 100), processing circuitry 122 may incorrectly determine the present capacity fade parameters, thereby incorrectly determining the weighted moving average incremental capacity fade and the resulting present capacity. As such, processing circuitry 122 may significantly overestimate or underestimate the present relative SOC of battery 100 which may be desirable to avoid.

Thus, processing circuitry 122 may determine if the present moving average voltage is stable enough for an OCV determination. If the present moving average voltage is not stable (the “NO” path from box 306), processing circuitry 122 may return to box 302 (or alternatively, to box 300).

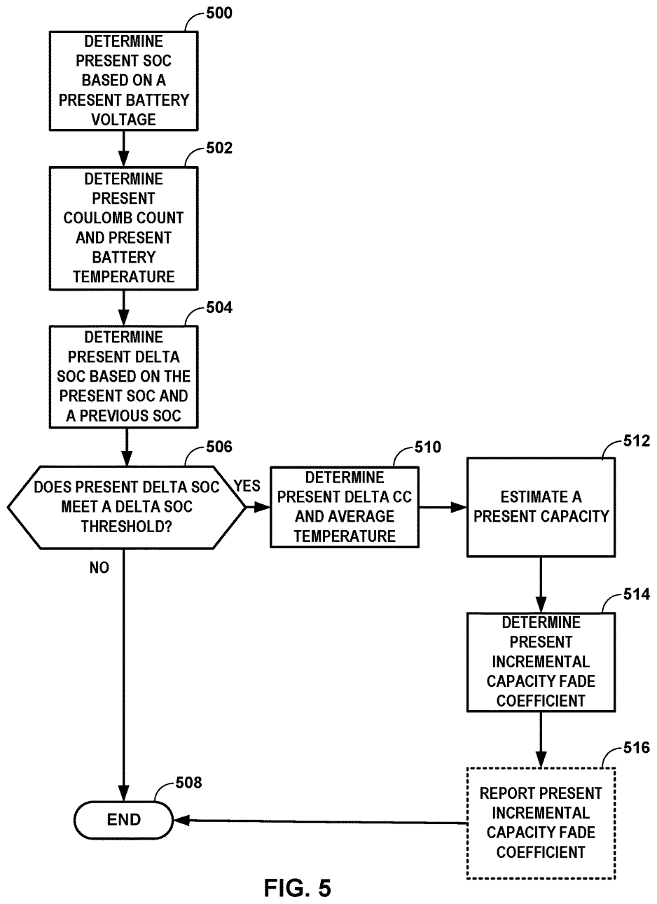

If BMS 110 is coming out of reset (the “YES” path from box 304) or if the present moving average voltage is stable (the “YES” path from box 306), processing circuitry 122 may determine present capacity fade parameters (308). For example, processing circuitry 122 may calculate the present incremental capacity fade coefficient, a present delta SOC, and a timestamp associated with the present incremental capacity fade coefficient and the present delta SOC. The calculation of the present incremental capacity fade coefficient and the present delta SOC are discussed further herein with respect to FIG. 5.

Processing circuitry 122 may determine respective freshness factors (310). For example, processing circuitry 122 may determine a respective freshness factor for one or more of the present capacity fade or previous capacity fades based on the timestamp associated with the present capacity fade and a respective timestamp associated with the respective previous capacity fade.

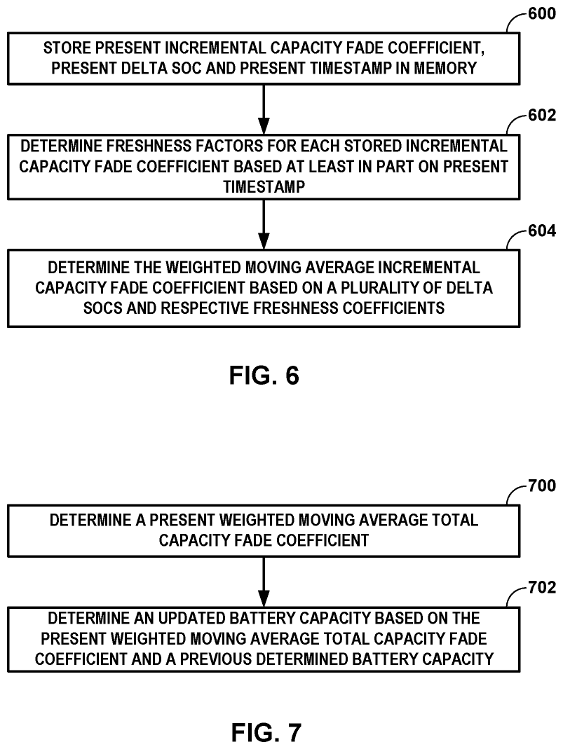

Processing circuitry 122 may determine a weighted moving average incremental capacity fade coefficient based on a plurality of incremental capacity fade coefficients, respective delta SOCs, and/or respective freshness factors (312). For example, processing circuitry 122 may apply a formula, such as that discussed below with respect to FIG. 6 to determine the weighted moving average incremental capacity fade.

Processing circuitry 122 may determine a present battery capacity based on the weighted moving average incremental capacity fade coefficient and a previous determined battery capacity (314). For example, processing circuitry 122 may subtract the weighted moving average incremental capacity fade coefficient from a previous determined battery capacity to determine the present battery capacity.

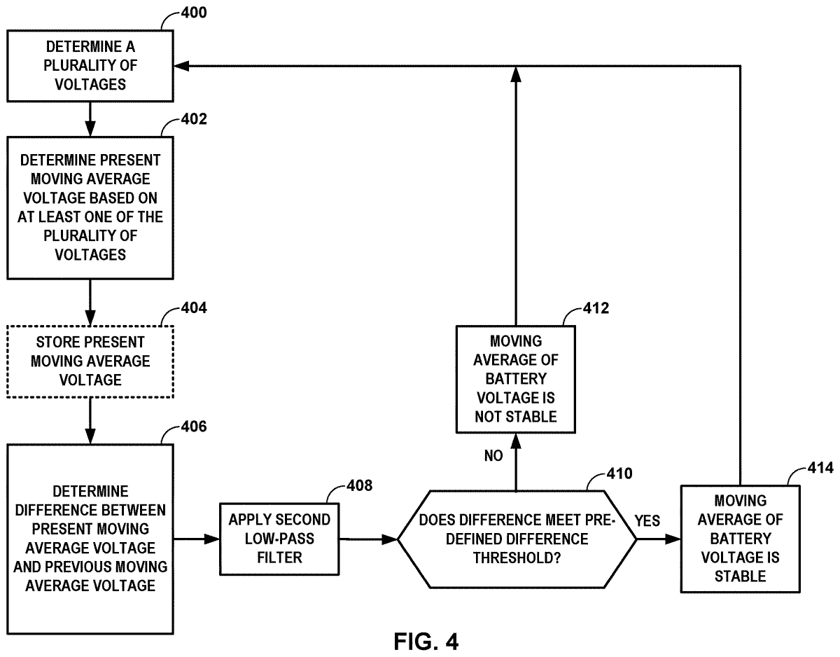

FIG. 4 is a flow diagram illustrating example techniques for determining whether the battery voltage is stable enough for an OCV determination according to one or more aspects of this disclosure. While discussed with respect to processing circuitry 122, the example of FIG. 4 may be performed by fuel gauge 110, processing circuitry 122, processing circuitry of another device(s) (e.g., one or more devices external to device 120), or any combination thereof.

Processing circuitry 122 may determine a plurality of battery voltages of battery 100 over time (400). Box 400 may be an example of box 300 of FIG. 3 and does not need to be, but may be, repeated if the determination of the plurality of battery voltages of battery 100 over time has already been performed. For example, processing circuitry 122 may obtain a plurality of voltages of battery 100 from voltage sensor 102 over time.

Processing circuitry 122 may determine a present moving average voltage based on the plurality of battery voltages (402). Box 402 may be an example of box 302 of FIG. 3 and does not need to be, but may be, repeated if the determination of the present moving average voltage has already been performed. For example, processing circuitry 122 may determine the present moving average voltage by applying a first low-pass filter of low-pass filters 138, such as a FIR low-pass filter to the plurality of voltages. The low-pass filter may be configured to utilize a limited time window such that all of plurality of battery voltages may not be used when determining the present moving average voltage. For example, the low-pass filter may only use a portion or subset of the plurality of battery voltages.

In some examples, the first low-pass filter may include a programmable sampling rate and/or time window. A low-pass filter having a programmable sampling rate and/or time window may be utilizable in different contexts, such as with batteries having different chemistries and/or operating temperatures and/or with devices having different uses and/or usage environments. As such, the moving average voltage determinations may be customized, e.g., by a manufacturer of device 120, based on the intended use(s), environment(s), or the like for device 120, for example by selecting an appropriate sampling rate and/or time window. In some examples, the determination of the present moving average voltage may be repeated at a programmed time period.

Processing circuitry 122 may store the present moving average voltage (404) in memory 124 such that the present moving average voltage may be available for future use by processing circuitry 122.

Processing circuitry 122 may determine a difference between the present moving average voltage and a previous moving average voltage (406) which may be stored in memory 124. For example, processing circuitry 122 may subtract the present moving average voltage from the previous moving average voltage to determine the voltage difference.

Processing circuitry 122 may apply a second low-pass filter (408) of low-pass filters 138 to the difference between the present moving average voltage and the previous moving average voltage. In some examples, the second low-pass filter is a FIR filter. This second low-pass filter may reduce the impact of noise on the voltage difference.

Processing circuitry 122 may determine if the filtered voltage difference meets a pre-defined difference threshold (410). For example, processing circuitry 122 may compare the filtered voltage difference to the pre-defined difference threshold. In some examples, the filtered voltage difference may meet the pre-defined difference threshold by being less than the pre-defined difference threshold. In some examples, the filtered voltage difference may meet the pre-defined difference threshold by being less than or equal to the pre-defined difference threshold. In some examples, the pre-defined difference threshold may be programmable. For example, different battery chemistries may utilize different thresholds, different battery operational temperatures may utilize different thresholds, and/or different use conditions (e.g., large pulse loads, for which a voltage may take a relatively long time to settle versus small consistent loads, for which a voltage may take a relatively short time, or no time, to settle) may utilize different thresholds.

If the filtered voltage difference does not meet the pre-defined difference threshold (the “NO” path from box 410), processing circuitry 122 may determine that the present moving average voltage is not stable (412). For example, processing circuitry 122 may provide an indication that the present moving average voltage is not stable. For example, if a voltage stable flag is currently asserted, processing circuitry 122 may de-assert the voltage stable flag.

If the filtered voltage difference meets the pre-defined threshold, (the “YES” path from box 410), processing circuitry 122 may determine that the present moving average voltage is stable (414). For example, processing circuitry 122 may provide an indication that the present moving average voltage is stable. For example, if a voltage stable flag is not asserted, processing circuitry 122 may assert the voltage stable flag.

In some examples, processing circuitry 122 may repeat the techniques of FIG. 4, e.g., continuously, when battery 100 is not under any charge or discharge load.

FIG. 5 is a flow diagram illustrating example techniques for determining the present capacity fade parameters according to one or more aspects of this disclosure. While discussed with respect to processing circuitry 122, the example of FIG. 5 may be performed by fuel gauge 110, processing circuitry 122, processing circuitry of another device(s) (e.g., one or more devices external to device 120), or any combination thereof.

Processing circuitry 122 may determine the present SOC based on the present battery voltage of a battery (e.g., battery OCV) (500). For example, processing circuitry 122 may look up the present battery voltage in an OCV to SOC lookup table of lookup tables/curves 128 in memory 124 to determine the present SOC.

Processing circuitry 122 may determine a present Coulomb count and present battery temperature (502). For example, processing circuitry 122 may obtain the present Coulomb count from Coulomb counter 108 and present battery temperature from temperature sensor 126.

Processing circuitry 122 may determine a present delta SOC based on the present SOC and a previous SOC (504). For example, processing circuitry 122 may determine the present delta SOC, dSOCp, as dSOCp=SOCp−SOCinit,

where SOCp is the present SOC and SOCinit is a previous SOC, such as an initial SOC.

Processing circuitry 122 may determine whether the present delta SOC (dSOCp) meets a delta SOC threshold (dSOCMin) (506). For example, processing circuitry 122 may compare the present delta SOC to the delta SOC threshold to determine whether the present delta SOC is meets the delta SOC threshold. For example, to meet the delta SOC threshold, in some examples, the present delta SOC may be greater than the delta SOC threshold, and in other examples, the present delta SOC may be greater than or equal to the delta SOC threshold. If the present delta SOC does not meet the delta SOC threshold (the “NO” path from box 506), processing circuitry 122 may end the capacity fade calculation (508) and not consider the present delta SOC for the capacity fade calculation (e.g., the present delta SOC may be too small to warrant consideration in the incremental capacity fade coefficient calculation). If the present delta SOC does meet the delta SOC threshold (the “YES” path from box 506), processing circuitry 122 may continue the capacity fade calculation using the present delta SOC.

Processing circuitry 122 may determine a present delta Coulomb count, dCC, and an average battery temperature (510). For example, processing circuitry 122 may determine the present delta Coulomb count as

dCC=CCp−CCinit,

where CCp is the present Coulomb count and the CCinit is a previous Coulomb count, such as an initial Coulomb count. Processing circuitry 122 may determine the average battery temperature, Tavg, as the average of a present battery temperature and one or more previously battery temperature(s).

Processing circuitry 122 may estimate a present battery capacity (512), e.g., based on the present delta CC and the present delta SOC. For example, processing circuitry 122 may estimate the present capacity at the average battery temperature (Tavg) as

CapMaxNew=dCC/dSOCp. This estimate of the present capacity may be refined or improved when determining the present battery capacity through the use of the weighted moving average incremental capacity fade coefficient and a previous determined battery capacity as is further discussed hereinafter. For example, the OCV-SOC lookup table may be one of a set of lookup tables, with one table for each battery temperature point. For example, if device 120 operates within 10 C to 30 C, there may be an OCV-SOC lookup table for 10 C, 20 C, and 30 C. Processing circuitry 122 may calculate the SOC based on the set of lookup tables and Tavg.

Processing circuitry 122 may determine the present incremental capacity fade coefficient (514). For example, processing circuitry 122 may determine the present incremental capacity fade coefficient as

dCapFade=CapMaxNew/CapMaxOld

where CapMaxOld is the previously measured battery capacity.

In some examples, processing circuitry 122 may determine a present total capacity fade coefficient, CapFadeNew. For example, processing circuitry 122 may determine a present total capacity fade coefficient as

CapFadeNew=CapFadeOld*dCapFade

where CapFadeOld is the previous total capacity fade coefficient.

In some examples, processing circuitry 122 may report the present incremental capacity fade coefficient (516). For example, processing circuitry 122 may store the present incremental capacity fade coefficient in parameters/values 136 for future use or may pass the present incremental capacity fade coefficient onto a separate algorithm or a different portion of a present algorithm that is being executed by processing circuitry 122. In some examples, processing circuitry 122 may do the same for the present total capacity fade coefficient.

FIG. 6 is a flow diagram illustrating example techniques for determining the weighted moving average of the incremental capacity fade coefficients according to one or more aspects of this disclosure. While discussed with respect to processing circuitry 122, the example of FIG. 6 may be performed by fuel gauge 110, processing circuitry 122, processing circuitry of another device(s) (e.g., one or more devices external to device 120), or any combination thereof.

Processing circuitry 122 may store the present incremental capacity fade coefficient, present delta SOC, and present timestamp in parameters 136 of memory 124 (600). For example, processing circuitry 122 may store the present capacity fade parameters in memory 124 for use in future weighted moving average of incremental capacity fade determinations.

Processing circuitry 122 may determine a freshness factor for each stored incremental capacity fade coefficient based at least in part on the present timestamp (602). For example, to reduce the effect of more stale incremental capacity fade coefficients, each incremental capacity fade coefficient may be weighted by a freshness factor, S. For example, processing circuitry 122 may determine the freshness factor for a given incremental capacity fade coefficient as

S=Max(0,(1−Tlapsed/Tfresh))

where Tlapsed is the time lapsed from the previous capacity fade update, calculated from the difference in timestamps. Tfresh is the time window where the incremental capacity fade coefficients may be used for averaging. When a given incremental capacity fade coefficient is older than the Tfresh, S is equal to 0 and the given incremental capacity fade coefficient has no impact on the averaging. In some examples, the time window where the incremental capacity fade coefficients may be used for averaging, Tfresh, is programmable. For example, a longer time (e.g., over one year) between a previous incremental capacity fade coefficient and a present incremental capacity fade coefficient may be too old for consideration. For example, the battery chemistry may have changed too much during the time to warrant much consideration of the old previous incremental capacity fade coefficient. In such a case the time window may not include incremental capacity fade coefficients over one year old, in which case S may equal 0 for incremental capacity fade coefficients over one year old. Also, in such a case a 364-day old incremental capacity fade coefficient may have an S very close to 0, while the present incremental capacity fade coefficient may have an S of 1 or very close to 1.

Additionally, or alternatively, in order to minimize the impact of larger measurement error from the smaller charge or discharge cycles, the present incremental capacity fade coefficient dCapFade may be weighted by delta SOC, dSOC. For example, a relatively larger dSOC may be more reliable (as there is a larger discharge or charge associated with a relatively larger dSOC), so a relatively larger dSOC may have a greater weight. A relatively smaller dSOC may be less reliable (as there is a smaller discharge or charge associated with a relatively smaller dSOC), so a relatively smaller dSOC may have a lower weight.

Processing circuitry 122 may determine the weighted moving average incremental capacity fade coefficient based on a plurality of delta SOCs and respective freshness factors (604). For example, processing circuitry 122 may determine the weighted moving average of incremental capacity fade coefficient as

$$Avg ( dCapFade ) = \frac{{\sum }_{i}^{N} {dSOC}_{i} * {S}_{i} * {dCapFade}_{i}}{{\sum }_{i}^{N} {dSOC}_{i} * {S}_{i}}$$

where Avg(dCapFade) is the weighted moving average incremental capacity fade coefficient, dSOC is a delta SOC, S is a freshness factor, dCapFade is an incremental capacity fade coefficient, i is a respective value of a total number of values, and N is a total number of stored incremental capacity fade coefficients.

FIG. 7 is a flow diagram illustrating example techniques for determining a present battery capacity according to one or more aspects of this disclosure. While discussed with respect to processing circuitry 122, the example of FIG. 7 may be performed by fuel gauge 110, processing circuitry 122, processing circuitry of another device(s) (e.g., one or more devices external to device 120), or any combination thereof.

Processing circuitry 122 may determine a present weighted moving average total capacity fade coefficient (700). For example, processing circuitry 122 may determine present weighted moving average total capacity fade coefficient, avg (CapFadeNew), as

Avg(CapFadeNew)=Avg(CapFadeOld)*Avg(dCapFade)

where Avg(CapFadeOld) is the previous weighted moving average total capacity fade coefficient.

Processing circuitry 122 may determine a present battery capacity based on the present weighted moving average total capacity fade coefficient and a previous determined battery capacity (702). For example, processing circuitry 122 may determine present battery capacity, Avg(CapMaxNew), as

Avg(CapMaxNew)=Avg(CapFadeNew)*Capacity_BOL

where Capacity_BOL is the battery beginning of life capacity. This present battery capacity may be an updated battery capacity which processing circuitry 122 may store in parameters/values 136. Processing circuitry 122 may use this present battery capacity to generate a more accurate relative SOC (e.g., present battery charge/Avg(CapMaxNew)) which processing circuitry 122 may output for display to a user. A more accurate relative SOC may better inform the user of when the user should recharge battery 100.

This disclosure includes the following non-limiting examples.

Example 1. A device comprising: a memory configured to store a plurality of capacity fade parameters; a battery; a temperature sensor, the temperature sensor being configured to sense a battery temperature of the battery; and processing circuitry coupled to the memory and the temperature sensor, the processing circuitry being configured to: determine a plurality of battery voltages of the battery over time; determine a present moving average voltage based on at least one of the plurality of battery voltages; determine at least one of that the battery is coming out of reset or that the moving average of the battery voltage is stable; based on the at least one of the battery coming out of reset or the moving average of the battery voltage being stable, determine present capacity fade parameters, the present capacity fade parameters comprising a present incremental capacity fade coefficient, a present delta state-of-charge (SOC), and a timestamp associated with the present incremental capacity fade coefficient and the present delta SOC; determine respective freshness factors; determine a weighted moving average incremental capacity fade coefficient based on plurality of incremental capacity fade coefficients, respective delta SOCs, and respective freshness factors; and determine a present battery capacity based on the weighted moving average incremental capacity fade coefficient and a previous determined battery capacity.

Example 2. The device of example 1, wherein as part of determining the present moving average voltage, the processing circuitry is configured to apply a first low-pass filter to the plurality of battery voltages to determine the present moving average voltage.

Example 3. The device of example 2, wherein the first low-pass filter comprises a finite impulse response (FIR) filter having a programmable sampling rate and a programmable time window.

Example 4. The device of example 2 or example 3, wherein as part of determining that the present moving average voltage is stable, the processing circuitry is configured to: determine a difference between the present moving average voltage and a previous moving average of the battery voltage over a programmable time period; apply a second low-pass filter to the difference to generate a filtered difference; and determine that the filtered difference meets a pre-defined difference threshold.

Example 5. The device of example 4, wherein the second low-pass filter comprises a finite impulse response (FIR) filter.

Example 6. The device of any of examples 1-5, wherein as part of determining the present capacity fade parameters, the processing circuitry is configured to: determine a present SOC based on a present determined battery voltage; determine a present Coulomb count (CC); determine a present battery temperature; determine a present delta SOC based on the present SOC and a previous SOC; determine that the present delta SOC meets a delta SOC threshold; determine a present delta CC based on the present CC and a previous CC; determine an average battery temperature based on the battery temperature and at least one previous battery temperature; estimate a present battery capacity based on the delta CC and the present delta SOC; and determine the present incremental capacity fade coefficient based on the estimated present battery capacity and a previous estimated battery capacity.

Example 7. The device of example 6, wherein the processing circuitry is further configured to determine a total capacity fade coefficient based on an original battery capacity and the present estimated battery capacity.

Example 8. The device of any of examples 1-7, wherein as part of determining the weighted moving average incremental capacity fade coefficient, the processing circuitry is configured to: store the present incremental capacity fade coefficient, the present delta SOC and a present timestamp associated with the present incremental capacity fade coefficient and the present delta SOC in the memory; determine a respective freshness factor for each stored incremental capacity fade coefficient based at least in part on the present timestamp; and determine the weighted moving average incremental capacity fade coefficient.

Example 9. The device of example 8, wherein as part of determining the weighted moving average incremental capacity fade coefficient, the processing circuitry is configured to determine

$$Avg ( dCapFade ) = \frac{{\sum }_{i}^{N} {dSOC}_{i} * {S}_{i} * {dCapFade}_{i}}{{\sum }_{i}^{N} {dSOC}_{i} * {S}_{i}}$$

where Avg(dCapFade) is the weighted moving average incremental capacity fade coefficient, dSOC is a delta SOC, S is a freshness factor, dCapFade is an incremental capacity fade coefficient, i is a respective value of a total number of values, and N is a total number of stored incremental capacity fade coefficients.

Example 10. The device of example 9, wherein as part of determining the present battery capacity based on the weighted moving average incremental capacity fade coefficient and the previous determined battery capacity, the processing circuitry is configured to: determine a present weighted average total capacity fade coefficient as Avg(CapFadeNew)=Avg(CapFadeOld)*Avg(dCapFade), where Avg(CapFadeNew) is the present weighted average total capacity fade coefficient and Avg(CapFadeOld) is the previous weighted moving average total capacity fade coefficient; and determine the present battery capacity as Avg(CapMaxNew)=Avg(CapFadeNew)*Capacity_BOL, where Avg(CapMaxNew) is the present battery capacity and Capacity_BOL is the battery beginning of life capacity.

Example 11. The device of any of examples 1-10, wherein the device comprises an implantable medical device, an insulin pump, or an autoclavable device.

Example 12. A method comprising: determining a plurality of battery voltages of a battery over time; determining a present moving average voltage based on at least one of the plurality of battery voltages; determining at least one of that the battery is coming out of reset or that the moving average of the battery voltage is stable; based on the at least one of the battery coming out of reset or the moving average of the battery voltage being stable, determining present capacity fade parameters, the present capacity fade parameters comprising a present incremental capacity fade coefficient, a present delta state-of-charge (SOC), and a timestamp associated with the present incremental capacity fade coefficient and the present delta SOC; determining respective freshness factors; determining a weighted moving average incremental capacity fade coefficient based on plurality of incremental capacity fade coefficients, respective delta SOCs, and respective freshness factors; and determining a present battery capacity based on the weighted moving average incremental capacity fade coefficient and a previous determined battery capacity.

Example 13. The method of example 13, wherein determining the present moving average voltage comprises applying a first low-pass filter to the plurality of battery voltages.

Example 14. The method of example 13, wherein the first low-pass filter comprises a finite impulse response (FIR) filter having a programmable sampling rate and a programmable time window.

Example 15. The method of example 13 or example 14, wherein determining the present moving average voltage is stable comprises: determining a difference between the present moving average voltage and a previous moving average of the battery voltage over a programmable time period; applying a second low-pass filter to the difference to generate a filtered difference; and determining that the filtered difference meets a pre-defined difference threshold.

Example 16. The method of example 15, wherein the second low-pass filter comprises a finite impulse response (FIR) filter.

Example 17. The method of any of examples 12-16, wherein determining the present capacity fade parameters comprises: determining a present SOC based on a present determined battery voltage; determining a present Coulomb count (CC); determining a present battery temperature; determining a present delta SOC based on the present SOC and a previous SOC; determining that the present delta SOC meets a delta SOC threshold; determining a present delta CC based on the present CC and a previous CC; determining an average battery temperature based on the battery temperature and at least one previous battery temperature; estimating a present battery capacity based on the delta CC and the present delta SOC; and determining the present incremental capacity fade coefficient based on the estimated present battery capacity and a previous estimated battery capacity.

Example 18. The method of example 17, further comprising determining a total capacity fade coefficient based on an original battery capacity and the present estimated battery capacity.

Example 19. The method of any of examples 12-18, wherein determining the weighted moving average incremental capacity fade coefficient comprises: storing the present incremental capacity fade coefficient, the present delta SOC and a present timestamp associated with the present incremental capacity fade coefficient and the present delta SOC in the memory; determining a respective freshness factor for each stored incremental capacity fade coefficient based at least in part on the present timestamp; and determining the weighted moving average incremental capacity fade coefficient.

Example 20. The method of example 19, wherein determining the weighted moving average incremental capacity fade coefficient comprises determining:

$$Avg ( dCapFade ) = \frac{{\sum }_{i}^{N} {dSOC}_{i} * {S}_{i} * {dCapFade}_{i}}{{\sum }_{i}^{N} {dSOC}_{i} * {S}_{i}}$$

where Avg(dCapFade) is the weighted moving average incremental capacity fade coefficient, dSOC is a delta SOC, S is a freshness factor, dCapFade is an incremental capacity fade coefficient, i is a respective value of a total number of values, and N is a total number of stored incremental capacity fade coefficients.

Example 21. The method of example 20, wherein determining the present battery capacity based on the weighted moving average incremental capacity fade coefficient and the previous determined battery capacity comprises: determining a present weighted average total capacity fade coefficient as Avg(CapFadeNew)=Avg(CapFadeOld)*Avg(dCapFade), where Avg(CapFadeNew) is the present weighted average total capacity fade coefficient and Avg(CapFadeOld) is the previous weighted moving average total capacity fade coefficient; and determining the present battery capacity as Avg(CapMaxNew)=Avg(CapFadeNew)*Capacity_BOL, where Avg(CapMaxNew) is the present battery capacity and Capacity_BOL is the battery beginning of life capacity.

Example 22. A non-transitory storage medium comprising instructions that when executed by one or more processors cause the one or more processors to: determine a plurality of battery voltages of a battery over time; determine a present moving average voltage based on at least one of the plurality of battery voltages; determine at least one of that the battery is coming out of reset or that the moving average of the battery voltage is stable; based on the at least one of the battery coming out of reset or the moving average of the battery voltage being stable, determine present capacity fade parameters, the present capacity fade parameters comprising a present incremental capacity fade coefficient, a present delta state-of-charge (SOC), and a timestamp associated with the present incremental capacity fade coefficient and the present delta SOC; determine respective freshness factors; determine a weighted moving average incremental capacity fade coefficient based on plurality of incremental capacity fade coefficients, respective delta SOCs, and respective freshness factors; and determine a present battery capacity based on the weighted moving average incremental capacity fade coefficient and a previous determined battery capacity.

Various examples have been described in the disclosure. These and other examples are within the scope of the following claims.

1. A device comprising:
a memory configured to store a plurality of capacity fade parameters;
a battery;
a temperature sensor, the temperature sensor being configured to sense a battery temperature of the battery; and
processing circuitry coupled to the memory and the temperature sensor, the processing circuitry being configured to:
determine a plurality of battery voltages of the battery over time;
determine a present moving average voltage based on at least one of the plurality of battery voltages;
determine at least one of that the battery is coming out of reset or that the moving average of the battery voltage is stable;
based on the at least one of the battery coming out of reset or the moving average of the battery voltage being stable, determine present capacity fade parameters, the present capacity fade parameters comprising a present incremental capacity fade coefficient, a present delta state-of-charge (SOC), and a timestamp associated with the present incremental capacity fade coefficient and the present delta SOC;
determine respective freshness factors;
determine a weighted moving average incremental capacity fade coefficient based on plurality of incremental capacity fade coefficients, respective delta SOCs, and respective freshness factors; and
determine a present battery capacity based on the weighted moving average incremental capacity fade coefficient and a previous determined battery capacity.

2. The device of claim 1, wherein as part of determining the present moving average voltage, the processing circuitry is configured to apply a first low-pass filter to the plurality of battery voltages to determine the present moving average voltage.

3. The device of claim 2, wherein the first low-pass filter comprises a finite impulse response (FIR) filter having a programmable sampling rate and a programmable time window.

4. The device of claim 2, wherein as part of determining that the present moving average voltage is stable, the processing circuitry is configured to:
determine a difference between the present moving average voltage and a previous moving average of at least one of the plurality of battery voltages over a programmable time period;
apply a second low-pass filter to the difference to generate a filtered difference; and
determine that the filtered difference meets a pre-defined difference threshold.

5. The device of claim 4, wherein the second low-pass filter comprises a finite impulse response (FIR) filter.

6. The device of claim 1, wherein as part of determining the present capacity fade parameters, the processing circuitry is configured to:
determine a present SOC based on a present determined battery voltage;
determine a present Coulomb count (CC);
determine a present battery temperature;
determine a present delta SOC based on the present SOC and a previous SOC;
determine that the present delta SOC meets a delta SOC threshold;
determine a present delta CC based on the present CC and a previous CC;
determine an average battery temperature based on the battery temperature and at least one previous battery temperature;
estimate a present battery capacity based on the delta CC and the present delta SOC; and
determine the present incremental capacity fade coefficient based on the estimated present battery capacity and a previous estimated battery capacity.

7. The device of claim 6, wherein the processing circuitry is further configured to determine a total capacity fade coefficient based on an original battery capacity and the present estimated battery capacity.

8. The device of claim 1, wherein as part of determining the weighted moving average incremental capacity fade coefficient, the processing circuitry is configured to:
store the present incremental capacity fade coefficient, the present delta SOC and a present timestamp associated with the present incremental capacity fade coefficient and the present delta SOC in the memory;
determine a respective freshness factor for each stored incremental capacity fade coefficient based at least in part on the present timestamp; and
determine the weighted moving average incremental capacity fade coefficient.

9. The device of claim 8, wherein as part of determining the weighted moving average incremental capacity fade coefficient, the processing circuitry is configured to determine
$$Avg ( dCapFade ) = \frac{{\sum }_{i}^{N} {dSOC}_{i} * {S}_{i} * {dCapFade}_{i}}{{\sum }_{i}^{N} {dSOC}_{i} * {S}_{i}}$$
where Avg(dCapFade) is the weighted moving average incremental capacity fade coefficient, dSOC is a delta SOC, S is a freshness factor, dCapFade is an incremental capacity fade coefficient, i is a respective value of a total number of values, and N is a total number of stored incremental capacity fade coefficients.

10. The device of claim 9, wherein as part of determining the present battery capacity based on the weighted moving average incremental capacity fade coefficient and the previous determined battery capacity, the processing circuitry is configured to:
determine a present weighted average total capacity fade coefficient as
Avg(CapFadeNew)=Avg(CapFadeOld)*Avg(dCapFade)
where Avg(CapFadeNew) is the present weighted average total capacity fade coefficient and Avg(CapFadeOld) is a previous weighted moving average total capacity fade coefficient; and
determine the present battery capacity as
Avg(CapMaxNew)=Avg(CapFadeNew)*Capacity_BOL
where Avg(CapMaxNew) is the present battery capacity and Capacity_BOL is the battery beginning of life capacity.

11. The device of claim 1, wherein the device comprises an implantable medical device, an insulin pump, or an autoclavable device.

12. A non-transitory storage medium comprising instructions that when executed by one or more processors cause the one or more processors to:
determine a plurality of battery voltages of a battery over time;
determine a present moving average voltage based on at least one of the plurality of battery voltages;
determine at least one of that the battery is coming out of reset or that the moving average of the battery voltage is stable;
based on the at least one of the battery coming out of reset or the moving average of the battery voltage being stable, determine present capacity fade parameters, the present capacity fade parameters comprising a present incremental capacity fade coefficient, a present delta state-of-charge (SOC), and a timestamp associated with the present incremental capacity fade coefficient and the present delta SOC;
determine respective freshness factors;
determine a weighted moving average incremental capacity fade coefficient based on plurality of incremental capacity fade coefficients, respective delta SOCs, and respective freshness factors; and
determine a present battery capacity based on the weighted moving average incremental capacity fade coefficient and a previous determined battery capacity.

13. A method comprising:
determining a plurality of battery voltages of a battery over time;
determining a present moving average voltage based on at least one of the plurality of battery voltages;
determining at least one of that the battery is coming out of reset or that the moving average of the battery voltage is stable;
based on the at least one of the battery coming out of reset or the moving average of the battery voltage being stable, determining present capacity fade parameters, the present capacity fade parameters comprising a present incremental capacity fade coefficient, a present delta state-of-charge (SOC), and a timestamp associated with the present incremental capacity fade coefficient and the present delta SOC;
determining respective freshness factors;
determining a weighted moving average incremental capacity fade coefficient based on plurality of incremental capacity fade coefficients, respective delta SOCs, and respective freshness factors; and
determining a present battery capacity based on the weighted moving average incremental capacity fade coefficient and a previous determined battery capacity.

14. The method of claim 13, wherein determining the present moving average voltage comprises applying a first low-pass filter to the plurality of battery voltages.

15. The method of claim 14, wherein the first low-pass filter comprises a finite impulse response (FIR) filter having a programmable sampling rate and a programmable time window.

16. The method of claim 14, wherein determining the present moving average voltage is stable comprises:
determining a difference between the present moving average voltage and a previous moving average of at least one of the plurality of battery voltages over a programmable time period;
applying a second low-pass filter to the difference to generate a filtered difference; and
determining that the filtered difference meets a pre-defined difference threshold.

17. The method of claim 16, wherein the second low-pass filter comprises a finite impulse response (FIR) filter.

18. The method of claim 13, wherein determining the present capacity fade parameters comprises:
determining a present SOC based on a present determined battery voltage;
determining a present Coulomb count (CC);
determining a present battery temperature;
determining a present delta SOC based on the present SOC and a previous SOC;
determining that the present delta SOC meets a delta SOC threshold;
determining a present delta CC based on the present CC and a previous CC;
determining an average battery temperature based on the present battery temperature and at least one previous battery temperature;
estimating a present battery capacity based on the delta CC and the present delta SOC; and
determining the present incremental capacity fade coefficient based on the estimated present battery capacity and a previous estimated battery capacity.

19. The method of claim 18, further comprising determining a total capacity fade coefficient based on an original battery capacity and the present estimated battery capacity.

20. The method of claim 13, wherein determining the weighted moving average incremental capacity fade coefficient comprises:
storing the present incremental capacity fade coefficient, the present delta SOC and a present timestamp associated with the present incremental capacity fade coefficient and the present delta SOC in memory;
determining a respective freshness factor for each stored incremental capacity fade coefficient based at least in part on the present timestamp; and
determining the weighted moving average incremental capacity fade coefficient.
